(19) United States
(12) Patent Application Publication
(10) Pub. No.: US 2010/0304147 A1
(43) Pub. Date: Dec. 2, 2010

(54) METHOD FOR COATING LAYERS WHICH CONTAIN NONPOLAR POLY-AROMATICS

(75) Inventors: Timo Meyer-Friedrichsen, Krefeld (DE); Udo Guntermann, Krefeld (DE)

Correspondence Address: CONNOLLY BOVE LODGE & HUTZ, LLP, P O BOX 2207, WILMINGTON, DE, 19899, US

(73) Assignee: H.C. Starck Clevios GmbH, Goslar (DE)

(21) Appl. No.: 12/740,876

(22) PCT Filed: Oct. 20, 2008
(86) PCT No.: PCT/EP08/64110

§ 371 Date: Aug. 10, 2010

(30) Foreign Application Priority Data
Nov. 1, 2007 (DE) 102007052522.4

(51) Int. Cl. H01L 51/46; H01L 51/54; B32B 27/08; B05D 5/12

(52) U.S. Cl. 428/411.1; 427/58

(57) ABSTRACT

The invention relates to a process for coating layers comprising nonpolar polyaromatics with conductive polymers, and to polymeric layers produced by this process.

The invention relates to a process for coating layers comprising nonpolar polyaromatics with conductive polymers, and to polymeric layers produced by this process. The field of molecular electronics has developed rapidly in the last 15 years with the discovery of stable organic conductive and semiconductive compounds. In this time, a multitude of compounds which have semiconductive, conductive or electrooptical properties has been found. It is generally understood that molecular electronics will not displace conventional semiconductor units based on silicon. Instead, it is assumed that molecular electronic components will open up new fields of use in which suitability for coating large areas, structural flexibility, processibility at low temperatures and low costs are required. Semiconductive organic compounds are currently being developed for fields of use such as organic field-effect transistors (OFETs), organic luminescence diodes (OLEDs), sensors and photovoltaic elements. An overview of organic semiconductors, integrated semiconductor circuits and applications thereof is described, for example, in Organic Electronics, Materials, Manufacturing and Applications, H. Klauk, Wiley VCH, 2006.

Some important representatives of semiconductive compounds are polyaromatics, for example alkyl-substituted polyfluorenes or polyalkylthiophenes. For polyfluorenes and fluorene copolymers, for example poly(9,9-dioctylfluorene-co-bithiophene) (I)

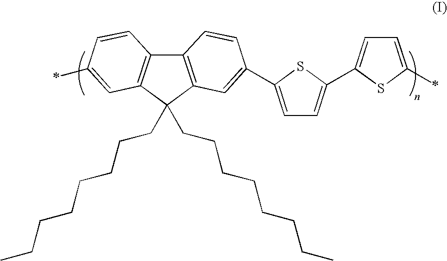

charge mobilities up to 0.02 cm²/Vs have been achieved (Science, 2000, Volume 290, p. 2123), and with regioregular poly(3-hexylthiophene-2,5-diyl) (II)

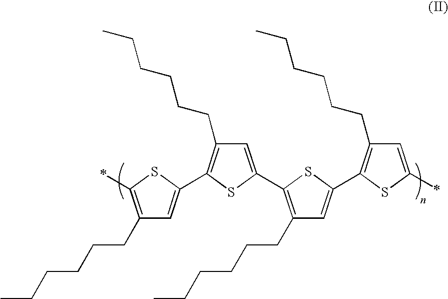

even charge mobilities up to 0.1 cm²/Vs (Science, 1998, Volume 280, p. 1741). Polyfluorene, polyfluorene copolymers and poly(3-hexylthiophene-2,5-diyl) form, like almost all long-chain polymers, good films after being applied from solution, and are therefore easy to process. In this context, the nonpolar alkyl substituents firstly provide the necessary solubility in common organic solvents, and they can secondly exert a directing effect on the order of the molecules in the thin layers produced therefrom, as shown, for example, in Adv. Mater. 2006, Volume 18, p. 860. These order effects are needed in order to enable a maximum mobility of the charges in the semiconductor layers. Frequently, poly(3-alkylthiophene) are utilized in the form of copolymers of 3-alkylthiophenes with different alkyl groups, since this brings an advantage in the solubility, and hence the applicability, of the polymers. Methods for preparing poly(3-alkylthiophenes) are described, for example, in Handbook of Conducting Polymers, 3rd edition, Volume: Conjugated Polymers, chapter 9.3.1 and the citations therein.

The production of electronic components requires the use of semiconductive and conductive materials. At present, noble metals such as silver or gold are frequently applied by vapour deposition processes or in the form of pastes by printing processes, for example, as conductor tracks. In order to be able to utilize the advantages of organic materials in the production of electronic components, however, the use of organic conductor materials is desirable. Organic conductive materials are, for example, polyanilines (PAM), polypyrroles (PPy), poly(3,4-ethylenedioxythiophenes) (PEDT) or poly(thienothiophenes) (PTT). The conductivity is generally achieved by positive charges which are distributed over the polymer chain and are compensated and stabilized by an appropriate counterion. The counterions used may be polyelectrolytes which simultaneously enable stable dispersions or solutions of the conductive polymers in polar solvents such as water or short-chain alcohols to be produced. Poly(3,4-ethylenedioxythiophene) is generally used in the form of an aqueous dispersion of a complex of PEDT (III) with polystyrenesulphonic acid (PSS) to give PEDT:PSS, as described, for example in EP 0440957.

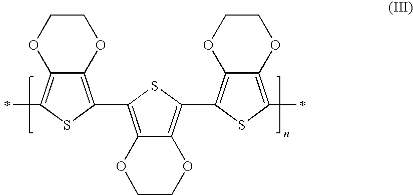

One possible structural formula of PEDT:PSS is shown in (IV). The structure possesses ionic character. The conductivity of the complex is generated through the doping of the PEDT chains with positive charges which are stabilized by the sulphonic acid groups of the PSS and ensure charge neutrality. An overview of the molecular structure and current fields of use of PEDT:PSS is given for example, in J. Mater. Chem. 2005, Volume 15, p. 2077.

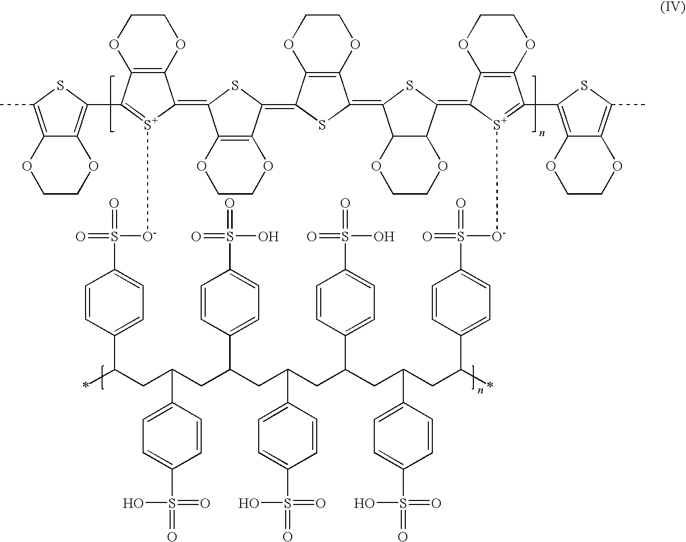

In the formulae (III) and (IV) the linkage to the other units is through the positions indicated with *.

A further possible form of a poly(dioxythiophene) is the water-soluble PEDT-S of the general formula (V), described, for example in EP 1122274,

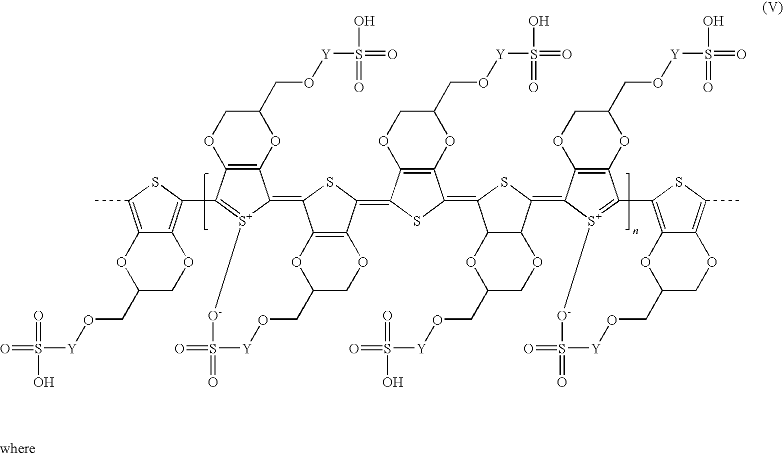

Y is a C₁-C₁₈ alkylene radical.

Dispersions or solutions with polyelectrolyte counterions, for example poly(styrenesulphonic acid) may in principle also be obtained from optionally substituted PANI (for example in Journal of the Electrochemical Society 1994, Volume 141(6), p. 1409, and Polymer 1994, Volume 35(15), p. 3193), PPy (for example in U.S. Pat. No. 5,665,498) or PTT (for example in US 2004/0074779 and Synth. Metals 2005, Volume 152, p. 177). PEDT:PSS is applied, for example, as a dispersion in polar solvents, preferably water, by means of appropriate application processes. A very widespread application process is, for example, the spin-coating process. A particularly elegant method is that of application by means of the inkjet process (IEEE Transactions on Electron Devices, Volume 52, 9, 2005, p. 1982-1987). In this process, the dispersion is applied to the substrate in the form of ultrafine droplets and dried. This process allows performance of structuring of the conductive layer during the application. According to the composition of the dispersions, films with conductivities of up to 500 S/cm are achieved. The production of electronic components requires the direct coating of semiconductive materials, for example polyalkylthiophenes, with conductive layers, for example PEDT:PSS. For example, in a so-called “top-contact” configuration of organic field-effect transistors (OFETs) the source and drain electrodes are applied to the semiconductor. The orthogonal polarities of the nonpolar polymeric semiconductors, for example poly(3-hexylthiophene-2,5-diyl) (P3HT), and the polar PEDT:PSS give rise to adhesion and wetting problems between these two layers, which prevent stable coating. IEEE Transactions on Electron Devices 2005, Volume 52, 9, p. 1982 describes OFET structures in which PEDT:PSS source and drain electrodes are below a P3HT semiconductor layer (“bottom contact” mode). There are no statements regarding the adhesion stability of the layers obtained.

The adhesion is typically determined with a “TESA test”, in which a strip of a pressure-sensitive adhesive roll is pressed briefly on to the layer and pulled off again. There is sufficient adhesion when this does not detach the layer from the layer below it.

The “top contact” configuration, in which the conductor tracks are applied to the semiconductor layer, is more advantageous than the “bottom contact” configuration in terms of printing and function. For this purpose, the nonpolar semiconductor layer has to be printed with a polar PEDT:PSS dispersion, which, though, is impossible owing to the hydrophobic surface. The addition of wetting agents, for example Dynol 604, Surfynol 104 E, Zonyl FF 300 or Triton X-100, does lead to wetting of the nonpolar surface, but the resulting PEDT:PSS layer fails the TESA test, irrespective of the coating method used, for example, spin-coating or knife-coating. Other auxiliary additives, for example, crosslinking agents, also do not lead to any improvement in adhesion of the PEDT:PSS on nonpolar alkyl-substituted polyaromatic layers.

It was thus an object of the present invention to provide a process with which polar conductive polymer layers can be applied to nonpolar organic layers, for example semiconductor layers, so as to obtain stable, firmly adhering and functioning structures. Such a method would enable the production of stable organic electronic components. It has now been found that, surprisingly, layers comprising nonpolar polyaromatics can be provided with a polar layer of at least one conductive polymer which has stable adhesion when the nonpolar layer is wetted beforehand with substituted alkanes. In particular, the resulting layers of at least one conductive polymer pass the TESA test and are conductive.

The invention thus provides a process for coating layers comprising nonpolar polyaromatics with conductive polymers, characterized in that the nonpolar layer is first wetted with substituted alkanes, and the layer thus obtained is then coated with at least one conductive polymer.

In a preferred embodiment of the invention, the layers comprising nonpolar polyaromatics comprise identical or different units formed from polyaromatics of the general formula (H)

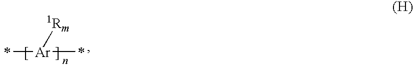

where
Ar represents identical or different aromatic units, preferably those consisting of thiophenyl, phenylenyl or fluorenyl units, more preferably thiophenyl units,
¹R is the same or different and independently represents identical or different, linear or branched C₄-C₂₀-alkyl radicals, mono- or polyunsaturated C₄-C₂₀-alkenyl radicals, or C₄-C₂₀-aralkyl radicals, preferably linear or branched C₄-C₂₀-alkyl radicals, more preferably linear C₄-C₂₀-alkyl radicals,
m is an integer of 0 to 2 and
n is an integer of 1, preferably of 1 to 1000, more preferably of 1-800, even more preferably of 1 to 400 and extremely preferably of 10 to 50.

In a particularly preferred embodiment of the invention, the layer comprising nonpolar polyaromatics comprises identical or different units formed from polyaromatics of the general formula (H-I)

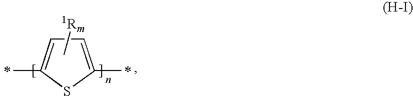

where
¹R represents identical or different, linear C₄-C₂₀-alkyl radicals,
m is 1, and
n is an integer ≧1, preferably of 1 to 1000, more preferably of 1-800, even more preferably of 1 to 400 and extremely preferably of 10 to 30.

In the general formulae (H) and (H-I) the linkage with the other units is via the positions indicated with “*”.

In the context of the invention, when different units of the polyaromatics of the general formula (H) and of the general formula (H-I) are used, one unit is preferably present at least 10 mol %.

The layers which comprise nonpolar polyaromatics and are used in the process according to the invention may be conductive or semiconductive, preferably conductive.

In the process according to the invention, the layer comprising nonpolar polyaromatics is preferably coated using at least one conductive polymer selected from the group consisting of an optionally substituted polythiophene, polyaniline or polypyrrole.

More preferably at least one conductive polymer is an optionally substituted polythiophene containing repeat units of the general formula (L-I) or repeat units of the general formula (L-II) or repeat units of the general formula (L-III) or repeat units of the general formulae (L-I) and (L-II) or repeat units of the general formulae (L-I) and (L-III) or repeat units of the general formulae (L-II) and (L-III) or repeat units of the general formulae (L-I), (L-II) and (L-III):

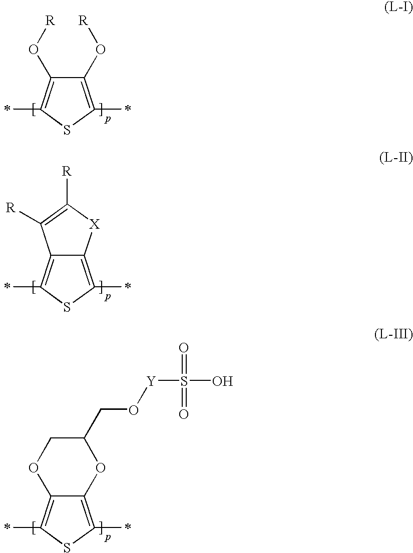

where
R is the same or different and independently represents identical or different, linear or branched C₁-C₂₀-alkyl radicals, mono- or polyunsaturated C₂-C₂₀-alkenyl radicals, C₇-C₂₀-aralkyl radicals or H, preferably linear or branched C₁-C₂₀-alkyl radicals, more preferably C₁-C₈-alkyl radicals, or together form an optionally substituted C₁-C₄-alkylene radical, preferably a C₂-alkylene radical,
X is O or S,
Y is as defined above, and
p is an integer of 3 to 100, preferably 5 to 50, more preferably 8 to 20.

Most preferably, at least one conductive polymer is a polythiophene containing repeat units of the general formula (L-IV)

not be considered to be exclusive.

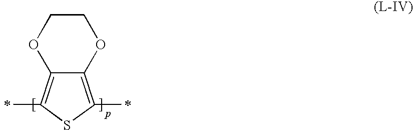

where
p is as defined above.

The abovementioned polythiophenes bear, on the end groups, preferably in each case H.

In the context of the invention, C₁-C₄-alkylene radicals are, for example, methylene, ethylene, n-propylene, or n-butylene. In the context of the invention, C₁-C₂₀-alkyl represents linear or branched C₁-C₂₀-alkyl radicals, for example methyl, ethyl, n- or isopropyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl, and C₂-C₂₀-alkenyl are, in the context of the invention, above-listed C₂-C₂₀-alkyl radicals containing at least one double bond. In the context of the invention, C₇-C₂₀-aralkyl represents C₇-C₁₈-aralkyl radicals, for example benzyl, o-, m-, p-tolyl, 2,3-, 2,4-, 2,5-, 2,6-, 3,4-, 3,5-xylyl or mesityl. The above list serves to illustrate the invention by way of example and should not be considered to be exclusive.

Any further substituents of the C₁-C₄-alkylene radicals may be numerous organic groups, for example alkyl, cycloalkyl, aryl, halogen, ether, thioether, disulphide, sulphoxide, sulphone, sulphonate, amino, aldehyde, keto, carboxylic ester, carboxylic acid, carbonate, carboxylate, cyano, alkylsilane and alkoxysilane groups and also carboxamide groups.

The conductive polymers or polythiophenes may be uncharged or cationic. In preferred embodiments, they are cationic, “cationic” relating only to the charges which reside on the polymer or polythiophene backbone. According to the substituent on the R radicals, the polymers or polythiophenes may bear positive and negative charges in the structural unit, in which case the positive charges are present on the polymer- or polythiophene backbone and the negative charges, if any, on the R radicals substituted by sulphonate or carboxylate groups. The positive charges of the polymer or polythiophene backbone may be partly or fully saturated by any anionic groups present on the R radicals. Viewed overall, the polymers or polythiophenes in these cases may be cationic, uncharged or even anionic. Nevertheless, they are all considered in the context of the invention to be cationic polymers or polythiophenes, since the positive charges on the polymer or polythiophene backbone are crucial. The positive charges are not shown in the formulae, since their exact number and position cannot be stated unambiguously. However, the number of positive charges is at least 1 and at most n, where n is the total number of all repeat units (identical or different) within the polymer or polythiophene. Cationic polymers or polythiophenes are also referred to hereinafter as polycations.

To compensate for the positive charge, if this has not already been done by the optionally sulphonate- or carboxylate-substituted and thus negatively charged R radicals, the cationic polymers or polythiophenes require anions as counterions.

Possible counterions are preferably polymeric anions, also referred to hereinafter as polyanions.

In a preferred embodiment of the present invention, at least one conductive polymer and at least one counterion are used for the coating.

Suitable polyanions include, for example, anions of polymeric carboxylic acids, such as polyacrylic acids, polymethacrylic acid or polymaleic acids, or anions of polymeric sulphonic acids, such as polystyrenesulphonic acids and polyvinylsulphonic acids. These polycarboxylic and polysulphonic acids may also be copolymers of vinylcarboxylic and vinylsulphonic acids with other polymerizable monomers, such as acrylic esters and styrene.

Particular preference is given, as the polymeric anion, to the anion of polystyrenesulphonic acid (PSS).

The molecular weight of the polyacids which afford the polyanions is preferably 1000 to 2 000 000, more preferably 2000 to 500 000. The polyacids or their alkali metal salts are commercially available, for example polystyrenesulphonic acids and polyacrylic acids, or else are preparable by known processes (see, for example, Houben Weyl, Methoden der organischen Chemie [Methods of Organic Chemistry], Vol. E 20 Makromolekulare Stolle [Macromolecular Substances], Part 2, (1987), p. 1141 ff.).

Cationic polythiophenes which contain anions as counterions for charge compensation are also often referred to in the technical field as polythiophene/(poly)anion complexes.

In a particularly preferred embodiment of the present invention, 3,4-poly(ethylenedioxythiophene) and polystyrenesulphonate are used for the coating.

The coating with conductive polymers is effected preferably from solution or dispersion. The polar dispersions or solutions of the conductive polymers may comprise further constituents, for example wetting agents or crosslinkers.

Wetting agents are, for example, Dynol 604, Surfinol 104 E, Zonyl 104 E or Triton X-100. The crosslinkers used may, for example, be epoxysilanes such as Silquest A 187, isocyanates, such as Crosslinker CX-100 or melamine resins such as Acrafix ML.

The abovementioned aqueous dispersions or solutions, preferably comprising 3,4-polyalkylenedioxythiophenes, can be prepared, for example, in analogy to the process described in EP 440 957. Useful oxidizing agents and solvents are likewise those listed in EP 440 957. In the context of this invention, an aqueous dispersion or solution is understood to mean a dispersion or solution which contains at least 50% percent by weight (% by weight) of water, preferably at least 90% by weight of water, and optionally, comprises solvents which are—at least partly—miscible with water, such as alcohols, e.g. methanol, ethanol, n-propanol, isopropanol, butanol or octanol, glycols or glycol ethers, e.g. ethylene glycol, diethylene glycol, propane-1,2-diol, propane-1,3-diol or dipropylene glycol dimethyl ether or ketones, for example acetone or methyl ethyl ketone. In the aqueous dispersion or solution, the solids content of optionally substituted polythiophenes, especially of optionally substituted polythiophenes containing repeat units of the general formula (L-I), may be between 0.05 and 5.0% by weight, preferably between 0.1 and 2.5% by weight.

Processes for preparing the monomeric precursors for the preparation of conductive polymers of the general formula (L-I) and derivatives thereof are known to those skilled in the art and are described, for example in L. Groenendaal, F. Jonas, D. Freitag, H. Pielartzik & J. R. Reynolds, Adv. Mater. 12 (2000) 481-494 and literature cited therein.

The monomers required for the preparation of the conductive polymers of the general formula (L-II) are described by O, Stephan et al. in J. Electroanal. Chem. 443, 1998, 217-226, and the monomers needed for the preparation of the conductive polymers of the general formula (L-III) are described by B. Lee et al. in Synth., Metals 152, 2005, 177-180.

In the context of the invention, derivatives of the above-listed thiophenes are understood to mean, for example, dimers or trimers of these thiophenes. Higher molecular weight derivatives, i.e. tetramers, pentamers etc. of the monomeric precursors are also possible as derivatives. The derivatives may be formed either from identical or different monomer units and may be used in pure form or else in a mixture with one another and/or with the aforementioned thiophenes.

Oxidized or reduced forms of these thiophenes and thiophene derivatives are, in the context of the invention, encompassed by the term “thiophenes and thiophene derivatives”, provided their polymerization forms the same conductive polymers as in the case of the above-listed thiophenes and thiophene derivatives.

The thiophenes may optionally be used in the form of solutions. Suitable solvents include in particular the following organic solvents which are inert under the reaction conditions: aliphatic alcohols such as methanol, ethanol, i-propanol and butanol; aliphatic ketones such as acetone and methyl ethyl ketone; aliphatic carboxylic esters such as ethyl acetate and butyl acetate; aromatic hydrocarbons such as toluene and xylene; aliphatic hydrocarbons such as hexane, heptane and cyclohexane; chlorohydrocarbons such as dichloromethane and dichloroethane; aliphatic nitriles such as acetonitrile, aliphatic sulphoxides and sulphones such as dimethylsulphoxide and sulpholane; aliphatic carboxamides such as methylacetamide, dimethylacetamide and dimethylformamide; aliphatic and araliphatic ethers such as diethyl ether and anisole. In addition, it is also possible to use water or a mixture of water with the aforementioned organic solvents as the solvent. Preferred solvents are alcohols and water, and also mixtures comprising alcohols or water, or mixtures of alcohols and water. Thiophenes which are liquid under the oxidation conditions can also be polymerized in the absence of solvents.

The aqueous dispersion or solution may additionally contain at least one polymeric binder. Suitable binders are polymeric, organic binders, for example polyvinyl alcohols, polyvinylpyrrolidones, polyvinyl chlorides, polyvinyl acetates, polyvinyl butyrates, polyacrylic esters, polyacrylamides, polymethacrylic esters, polymethacrylamides, polyacrylonitriles, styrene/acrylic ester, vinyl acetate/acrylic ester and ethylene/vinyl acetate copolymers, polybutadienes, polyisoprenes, polystyrenes, polyethers, polyesters, polycarbonates, polyurethanes, polyamides, polyimides, polysulphones, melamine-formaldehyde resins, epoxy resins, silicone resins or celluloses. The solids content of polymeric binder is between 0 and 3% by weight, preferably between 0 and 1% by weight.

The nonpolar polymeric layers are wetted by the process according to the invention preferably using substituted alkanes of the general formula (A)

³R-Q (A)
where
³R is a linear or branched C₄-C₂₀-alkyl radical,
Q is —OH, —N⁴R⁵R, —SH, —COO⁴R, —CON⁴R⁵R, —PO(O⁴R), —SO₃⁴R or —SO₂N⁴R⁵R, and
⁴R and ⁵R are each independently optionally substituted, linear or branched C₁-C₂₀-alkyl radicals or H.

The substituted alkane of the general formula (A) preferably comprises alcohols, i.e. Q is —OH. Particular preference is given to primary alcohols having a linear alkyl ³R radical, very particular preference to primary alcohols having a linear C₄-C₁₂-alkyl ³R radical.

In the context of the invention, a linear or branched C₁-C₂₀-alkyl radical is, for example, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl or n-eicosyl.

Possible substituents of the C₁-C₂₀-alkyl radicals include numerous organic groups, for example alkyl, cycloalkyl, aryl, halogen, ether, thio ether, disulphide, sulphoxide, sulphone, sulphonate, amino, aldehyde, keto, carboxylic ester, carboxylic acid, carbonate, carboxylate, cyano, alkylsilane and alkoxysilane groups, and also carboxamide groups.

The substituted alkanes may be used as individual components or as a mixture of different substituted alkanes.

After being wetted with the substituted alkane of the general formula (A) preference is given to heat treating the nonpolar layer comprising polyaromatics of the general formula (H) at 40-200° C., preferably 60-150° C., most preferably at 80-130° C.

The layer which comprises nonpolar polyaromatics and has been treated with the substituted alkane of the general formula (A) is subsequently coated with a dispersion or solution comprising at least one conductive polymer by, for example, knife-coating, spin-coating or printing techniques, for example inkjet printing.

The substituted alkane and the polar solutions or dispersions can be applied to the nonpolar semiconductor layer by the known processes, for example, by spraying, dipping, printing and knife-coating. Particular preference is given to application by spin-coating and by inkjet printing.

The invention further provides polymeric layers produced by the process according to the invention, the use of these polymeric layers in electronic components such as field-effect transistors, light-emitting components such as organic luminescent diodes, or photovoltaic cells, lasers and sensors, and also these electronic components.

The layers produced by the process according to the invention can be modified further after the application, for example by a thermal treatment, for example passing through a liquid-crystalline phase or for structuring, for example by laser ablation.

The examples which follow serve to illustrate the invention by way of example and should not be interpreted as a restriction.

### EXAMPLES

The polymeric semiconductor compounds used were synthesized by known processes from, for example, McCullough et al. in J. Org. Chem. 1993, Volume 58, p. 904 or U.S. Pat. No. 6,166,172:

To this end, a freshly prepared solution of lithium diisopropylamide formed from 15 mmol of butyllithium and 15 mmol of diisopropylamine in 75 ml of THF was initially charged at −78° C. and admixed with the appropriate 2-bromo-3-alkylthiophenes. The solution was first stirred at −40° C. for a further 40 minutes, then admixed with 15 mmol of magnesium bromide etherate at −60° C. and stirred at −60° C. for a further 20 minutes. The reaction solution was then stirred at −40° C. for 15 minutes, before it was warmed to −5° C. within 30 minutes. At −5° C., 40 mg of Ni(dppp)Cl₂ were added, and the solution was stirred at room temperature overnight. The poly(3-alkylthiophene) formed was precipitated by adding methanol, filtered off, washed with methanol and water and dried under reduced pressure.

The PEDT:PSS dispersion used was the following standard formulation:

PEDT:PSS formulation: 42.92% by weight of Baytron P from H. C. Starck GmbH, 2.58% by weight of N-methyl-2-pyrrolidinone, 0.86% by weight of Silquest A 187 from GE-Bayer Silicones, 53.34% by weight of isopropanol and 0.30% by weight of Dynol 604 from Air Products. A 4-6 μm wet film layer of the formulation possesses, after drying, a surface resistivity of 10⁴ Ω/ [symbol] .

TESA Test: In the TESA test, a strip of a pressure-sensitive adhesive roll is pressed briefly on to the layer and pulled off again. There is sufficient adhesion when this does not detach the layer from the layer below it.

### Example 1

A PET film coated with poly(3-hexylthiophene) was wetted by spin-coating with a 4-6 μm thick wet film layer of commercially available 1-butanol. The moist film was heat treated at 80° C. for 10 minutes. Thereafter, a layer of the PEDT:PSS formulation with a wet film thickness of 4-6 μm was applied by spin-coating and then dried at 80° C.

The PEDT:PSS layer possessed a surface resistivity of 10⁴ Ω/ [symbol] . The PEDT:PSS layer passed the TESA test.

### Example 2

A PET film coated with poly(3-hexylthiophene) was wetted by spin-coating with a 4-6 μm thick wet film layer of commercially available 1-octanol. The moist film was heat treated at 130° C. for 10 minutes. Thereafter, a layer of the PEDT:PSS formulation with a wet film thickness of 4-6 μm was applied by spin-coating and then dried at 80° C.

The PEDT:PSS layer possessed a surface resistivity of 10⁴ Ω/ [symbol] . The PEDT:PSS layer passed the TESA test.

### Example 3

A PET film coated with poly(3-alkylthiophene) consisting of a copolymer of 90 mol % of commercially available 3-hexylthiophene and 10 mol % of commercially available 3-decylthiophene, was wetted by spin-coating with a 4-6 μm thick wet film layer of commercially available 1-octanol. The moist film was heat treated at 130° C. for 10 minutes. Thereafter, a layer of the PEDT:PSS formulation with a wet film thickness of 4-6 μm was applied by spin-coating and then dried at 80° C.

The PEDT:PSS layer possessed a surface resistivity of 10⁴ Ω/ [symbol] . The PEDT:PSS layer passed the TESA test.

### Comparative Example 1

A 4-6 μm thick wet film layer of the PEDT:PSS formulation was applied by spin-coating to a PET film coated with poly(3-hexylthiophene) and then dried at 80° C.

The PEDT:PSS layer possessed a surface resistivity of 10⁴ Ω/ [symbol] . The PEDT:PSS layer failed the TESA test.

### Comparative Example 2

A 4-6 μm thick wet film layer of the PEDT:PSS formulation was applied by spin-coating to a PET film coated with poly(3-alkylthiophene), consisting of a copolymer of 90 mol % of 3-hexylthiophene and 10 mol % of 3-decylthiophene, and then dried at 80° C.

The PEDT:PSS layer possessed a surface resistivity of 10⁴ Ω/ [symbol] . The PEDT:PSS layer failed the TESA test.

### Comparative Examples 3-9

A 4-6 μm thick wet film layer of a dispersion consisting of 90-99% by weight of the PEDT:PSS formulation and 1-10% by weight of a further auxiliary additive was applied by spin-coating to a PET film coated with poly(3-alkylthiophene), consisting of a copolymer of 90 mol % of 3-hexylthiophene and 10 mol % of 3-decylthiophene, and then dried at 80° C. The auxiliary additives used and the results of the corresponding coating are listed in Table 1. In each case, 2% by weight of auxiliary additive was always used. The surface resistivity of the PEDT:PSS layer in comparative examples 3-9 was in each case 10⁴ Ω/ [symbol] .

TABLE 1

| Comparative | | | |
|---|---|---|---|
| example | Auxiliary additive | Wetting | TESA test |
| 3 | vinyltrimethoxysilane | yes | failed |
| 4 | N-phenyl-3- | yes | failed |
| | aminopropyl- | | |
| | trimethoxysilane | | |
| 5 | methacryloxypropyltri- | yes | failed |
| | methoxysilane | | |
| 6 | Acrafix ML | yes | failed |
| | (melamine resin) | | |
| 7 | isocyanate | yes | failed |
| 8 | Aquacer 539 | yes | failed |
| | (wax emulsion) | | |
| 9 | acryloylmorpholine | yes | failed |

As is evident from Table 1, the use of the auxiliary additives effects wetting, but the layers have insufficient adhesion since they fail the TESA test.

### Comparative Example 10

A 4-6 μm thick wet film layer of the PEDT:PSS formulation containing 1% by weight of octanol was applied by spin-coating to a PET film coated with poly(3-alkylthiophene), consisting of a copolymer of 90 mol % of 3-hexylthiophene and 10 mol % of 3-decylthiophene, and then dried at 80° C.

The PEDT:PSS layer possessed a surface resistivity of 10⁴ Ω/ [symbol] . The PEDT:PSS layer failed the TESA test.

1.-14. (canceled)

15. A process for coating layers comprising nonpolar polyaromatics with conductive polymers, which comprises first wetting a nonpolar layer with substituted alkanes and then coating with at least one conductive polymer.

16. The process according to claim 15, wherein the nonpolar layer comprises identical or different units formed from polyaromatics of the formula (H) 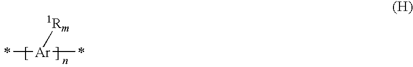
wherein
Ar represents identical or different aromatic units,
¹R is the same or different and independently of each other represents identical or different, linear or branched C₄-C₂₀-alkyl radicals, mono- or polyunsaturated C₄-C₂₀-alkenyl radicals, or C₄-C₂₀-aralkyl radicals,
m is an integer from 0 to 2 and
n is an integer ≧1.

17. The process according to claim 16, wherein Ar represents identical or different aromatic units selected from the group consisting of thiophene, phenylene and fluorenyl units.

18. The process according to claim 15, wherein the nonpolar layer comprises identical or different units formed from polyaromatics of the general formula (H-I), 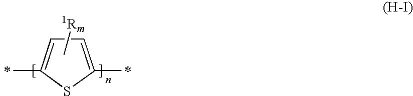
wherein
¹R independently of each other represents identical or different, linear C₄-C₂₀-alkyl radicals,
m is 1, and
n is an integer ≧1.

19. The process according to claim 15, wherein at least one conductive polymer is an optionally substituted polythiophene, polyaniline or polypyrrole.

20. The process according to claim 19, wherein at least one conductive polymer is an optionally substituted polythiophene comprising repeating units of the formula (L-I), (L-II), or (L-III) or a mixture thereof, 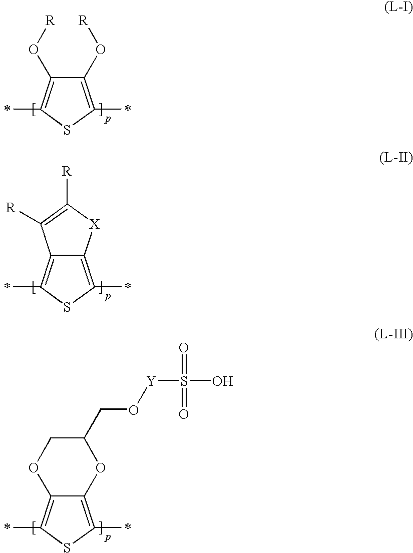
wherein
R is the same or different and independently of each other represents identical or different, linear or branched C₁-C₂₀-alkyl radicals, mono- or polyunsaturated C₂-C₂₀-alkenyl radicals, C₇-C₂₀-aralkyl radicals or H, or together form an optionally substituted C₁-C₄-alkylene radical,
X is O or S,
Y represents linear or branched C₁-C₂₀-alkylene radicals, mono- or polyunsaturated C₂-C₂₀-alkenyl radicals or C₁-C₂₀-aralkyl radicals, and
p is independently of each other an integer of from 3 to 100.

21. The process according to claim 20, wherein at least one conductive polymer is a polythiophene comprising repeating units of the formula (L-IV), 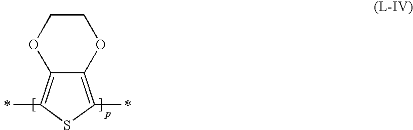
wherein
p is an integer of 3 to 100.

22. The process according to claim 15, wherein at least one conductive polymer and at least one counterion are used for the coating.

23. The process according to claim 22, wherein 3,4-poly(ethylenedioxythiophene) and polystyrenesulphonate are used for the coating.

24. The process according to claim 15, wherein substituted alkanes of the formula (A)
³R-Q (A),
wherein
³R is a linear or branched C₄-C₂₀-alkyl radical,
Q represents —OH, —N⁴R⁵R, —SH, —COO⁴R, —CON⁴R⁵R, —PO(O⁴R), —SO₃⁴R or —SO₂N⁴R⁵R,
and
⁴R and ⁵R independently of each other represent optionally substituted, linear or branched C₁-C₂₀-alkyl radicals or H,
are used for wetting.

25. The process according to claim 24, wherein Q is —OH.

26. The process according to claim 15, wherein the nonpolar layer is heat treated at 40-200° C. after being wetted with the substituted alkane.

27. A polymeric layer which has been produced by the process according to claim 15.

28. An electronic component comprising the polymeric layer according to claim 27.
